(19) United States
(12) Patent Application Publication
(10) Pub. No.: US 2009/0257839 A1
(43) Pub. Date: Oct. 15, 2009

(54) COATING METHOD FOR DRILL BITS

(76) Inventor: YU-HSUEH LIN, TAIPEI CITY (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/266,910

(22) Filed: Nov. 7, 2008

(30) Foreign Application Priority Data
Apr. 14, 2008 (TW) 097113480

(51) Int. Cl. B23B 51/02; B05D 3/02; C23C 16/02; C23C 16/513

(52) U.S. Cl. 408/199; 427/314; 427/534

(57) ABSTRACT

A method for film-coating drill bits comprises the steps of: providing a core drill bit; cleaning and further heating the core drill bit; forming an adherent film on the core drill bit; forming a mixing film on the adherent film; and forming a non-crystalline diamond-like film on the mixing film. The finish film-coated drill bit comprises an inner adherence film, a middle mixing film and an outer non-crystalline diamond-like carbon (DLC) film. The mixing film is composed of a non-crystalline diamond-like material and compositions of the adherence film. In the mixing film, the composition of the non-crystalline diamond-like material is higher in a position close to the DLC film.

This application claims the benefit of Taiwan Patent Application Serial No. 097113480, filed Apr. 14, 2008, the subject matter of which is incorporated herein by reference.

### BACKGROUND OF THE INVENTION

1. Field of the Invention

The present invention relates to a finish method for drill bits, and in particular to a film coating method to finish the drill bits.

2. Description of Related Art

In machining, drills are usually used to form a hole on a work piece. To forming a small-size hole (in the scale of micrometers or nanometers), a micro-drill bit can be promptly used to settle the drilling on the work piece, though the electrical discharge machining might be another clever choice.

Especially, when a conductive hole is wanted at a multi-layered circuit board, drilling using a micro drill bit is usually chosen for its lesser machining tolerance. It is noted that, when the micro drill bit is utilized, a blunt head from grounding or wearing in operations has an adverse impact on machining accuracy. Thus, to replace the micro drill bit in time is very an important part in mass-producing the multi-layered circuit boards. Meanwhile, the service life of the micro drill bit is also another issue in costing the manufacturing by such drilling, for frequently replacing the micro drill bits will definitely lead to an increase in producing the multi-layered circuit boards.

To prolong the service life of the micro drill bit, it is usually to coat a non-crystalline Diamond-like carbon (DLC) film on the micro drill bit. The non-crystalline DLC material is mainly consisted of a compact structure with carbons and hydrogens, providing valence electrons in sp2 and sp3 hybridized orbits. In the art, the non-crystalline DLC is similar in structuring to a natural diamond. Both of them have some the same advantages in hardness, heat-resistance, and rust-proofing. Thus, if the non-crystalline DLC film is coated on the micro drill bit, then the drill bit would have better performances in cutting, swarf-removal, wear-resistance and heat-resistance.

However, due to high hardness of the non-crystalline DLC film, the adhesion in between with the original drill bit material is substantially weak. In addition, if the thickness of the DLC film is increased, then the internal stress of the DLC films will be increased as well. As soon as the internal stress is lager than a certain value, the DLC film will crack and be peeled from the micro drill bit. Thus, for preventing the DLC film from peeling from the micro drill bit, the thickness of the DLC film on the drill bit must be thin enough.

To achieve the DLC film on the micro drill bit and to increase the thickness of the DLC film, it is necessary to develop a method for coating the drill bit so as to have the aforesaid disadvantages.

### SUMMARY OF THE INVENTION

Accordingly, the primary object of the present invention is to provide a method for film-coating drill bits and also the structure of the coated drill bit. The coating method for drill bits of a drill includes the steps of providing a drill bit; cleaning surface of the drill bit and heating the drill bit; forming an adherent film on the drill bit; forming a mixing film on the adherent film; and forming a non-crystalline Diamond-Like Carbon (DLC) film on the mixing film.

In the present invention, a surface structure of a finish drill bit prepared by the aforesaid coating method includes an adherent film, a mixing film, and a non-crystalline DLC film. The mixing film is made of a non-crystalline DLC material and an adhesion material. While in forming the mixing film, the outer portion of the mixing film has a higher composition of the DLC material.

Namely, the distribution of the DLC material within the mixing film is gradually varying within the mixing film. Thus, through the interfacing of the mixing film, the adherent film and the DLC film can co-exist with each other to surface the drill bit.

Due to indirect coating relationship between the DLC film and the core drill bit, the film-coated drill bit can provide better performance in cutting and wear-resistance. Generally speaking, it is well known that the cutting performance of the drill bit depends mainly on its ability in swarf-removal. Due that the DLC material presents high thermal conductivity and the DLC film of the present invention is not prone to be peeled, it is definitely feasible in accordance with the present invention to form a thinker DLC layer on the drill bit so as to achieve better performance in cutting and heat-resistance.

Thus, by providing the present invention to firmly form a thicker DLC coating film, a drill bit, or in particular a micro drill bit, can present better performance in cutting, swarf-removal, wear-resistance and heat-resistance. As the service life of the drill bit is increased by the DLC film, cost for replacing drill bits in drilling operations can be substantially reduced.

### BRIEF DESCRIPTION OF THE DRAWINGS

The present invention can be fully understood from the following detailed description and preferred embodiment with reference to the accompanying drawings, in which:

FIG. 1 illustrates schematically a preferred equipment for film-coating drill bits according to the present invention;

FIG. 2 illustrates that a drill bit is mounted on a conductive rack, and an external power is presented to generate a bias electric field according to the present invention;

FIG. 3 illustrates that a gas is introduced into a vacuum environment for being dissociated into a plasma by the bias electric field;

FIG. 4 illustrates that an adherent film is formed on the drill bit according to the present invention;

FIG. 5 is an enlarged cross-sectional view of area X of FIG. 4;

FIG. 6 illustrates that a mixing film is formed on the adherent film of the drill bit according to the present invention;

FIG. 7 is an enlarged cross-sectional view of area Y of FIG. 6 according to the present invention;

FIG. 8 illustrates that a DLC film is coated on the mixing film of the present invention; and

FIG. 9 is an enlarged cross-sectional view of area Z of FIG. 8 according to the present invention.

### DETAILED DESCRIPTION OF THE PREFERRED EMBODIMENTS

The following detailed description is of the best presently contemplated modes of carrying out the invention. This description is not to be taken in a limiting sense, but is made merely for the purpose of illustrating general principles of embodiments of the invention. The scope of the invention is best defined by the appended claims.

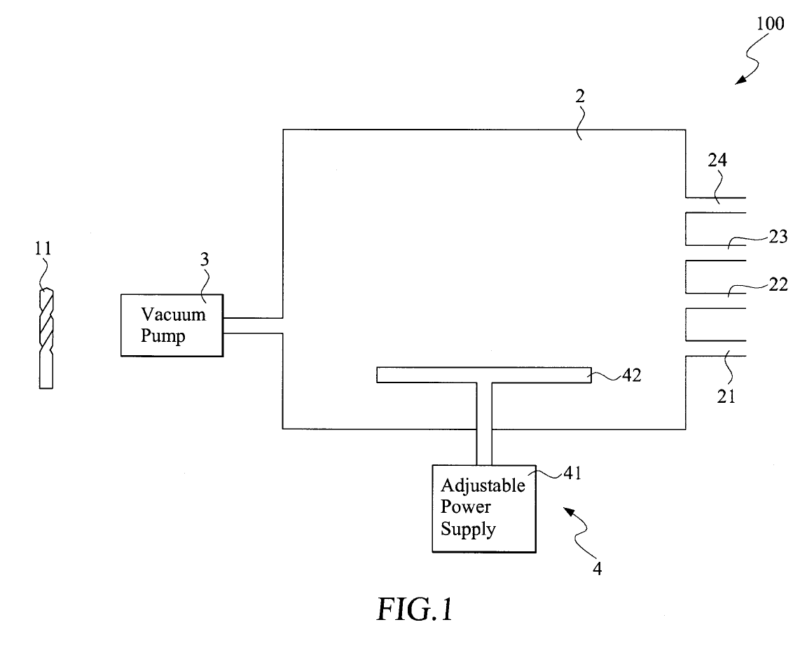

Referring to FIG. 1, it illustrates a schematic view of a preferred film-coating equipment 100 according to the present invention. As shown, a drill bit 11 is to be coated in the film-coating equipment 100. The film-coating equipment 100 includes a coating chamber 2, a vacuum pump 3, and an electrical control device 4. The coating chamber 2 further includes four inlets 21, 22, 23 and 24. The vacuum pump 3 is spatially in communication with the coating chamber 2. The electrical control device 4 further includes an adjustable power supply 41 and a conductive frame 42. The adjustable power supply 41 is positioned outside the coating chamber 2, while the conductive frame 2 extended from the adjustable power supply 41 is mainly located inside the coating chamber 2.

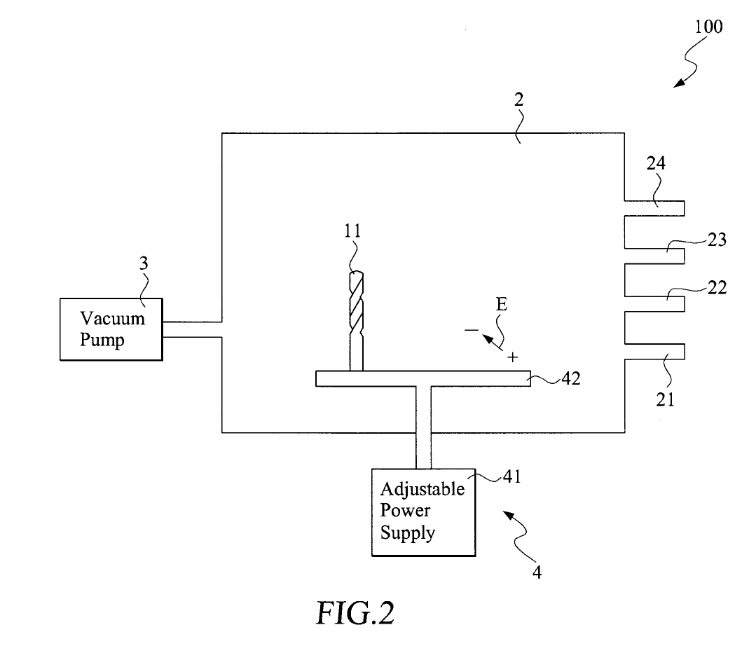

Referring to FIGS. 2-9, these drawings are illustrated for a preferred embodiment of the coating method for drill bits in accordance with the present invention. Referring to FIG. 2, the drill bit 11 is positioned readily at the conductive frame 42 electrically connected with the adjustable power supply 41. Then, a bias electrical field provided by the electrical power can be generated in the vacuum environment 2 pumped down by the vacuum pump 3. Meanwhile, the adjustable power supply 41 applies electrical power to the conductive frame 42 so that voltage of the conductive frame 42 as well as the drill bit 11 is higher than that of the vacuum environment within the coating chamber 2. In this light, a bias electrical field E is generated due to voltage difference between the conductive frame 42 and the coating chamber 2.

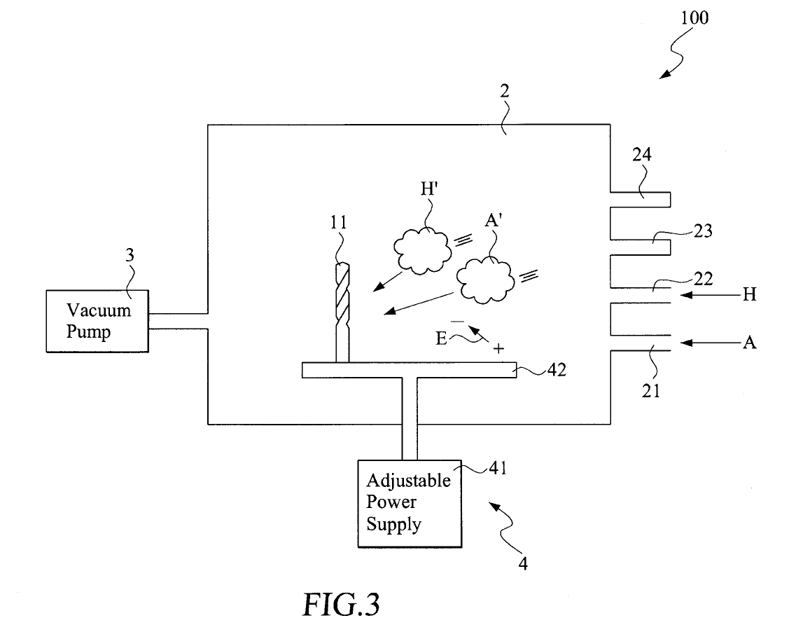

Referring to FIG. 3, it illustrates a gas is introduced into the vacuum environment inside the coating chamber 2, in which the gas is subjected to the bias electrical field E so as to be converted into a plasma or plasma-like material. As shown in FIG. 3, when the drill bit 11 is subjected to the coating process, the inlets 21 and 22 are opened to respectively feed a hydrogen gas (H₂) and an argon gas (Ar) into the coating chamber 2, while the inlets 23 and 24 are closed. The hydrogen gas (H₂) and the argon gas (Ar) into the coating chamber 2 are decomposed into two plasma or plasma-like materials by the bias electrical field E. Namely, in the coating chamber 2, hydrogen ions H⁺ and argon ions Ar⁺ are generated. Further, driven by the bias electrical field E, the hydrogen ions H⁺ and the argon ions Ar⁺ are led to bombard the drill 11 so as to produce a shower cleaning upon the drill bit 11.

In the beginning, flow rates for the hydrogen gas (H₂) and the argon gas (Ar) are preferably a 20 sccm (standard cc/min) and a 50 sccm, respectively. The adjustable power supply 41 provides an electrical power with an initial value of 300 Watts, and the bias voltage of the bias electrical field E is 300V. The vacuum pressure inside the coating chamber 2 is 1.5˜4 μbar. After an about 20-minute operation, the flow rates of the hydrogen gas (H₂) and the argon gas (Ar) can then be respectively increased to 45˜60 sccm and 200˜250 sccm, power of the adjustable power supply 41 can be adjusted to 600 Watts, and the vacuum pressure is increased to 4˜7 μbar. After a furthermore 30-minute operation, power of the adjustable power supply 41 can be further adjusted to 1000 Watts, the bias voltage of the bias electrical field E is 550V, and other parameters such as flow rates of the hydrogen gas (H₂) and the argon gas (Ar) and the vacuum pressure within the coating chamber 2 stays the same. Such a treatment is maintained for another 20 minutes so as to thoroughly clean the drill bit 11 and heat up the drill bit 11 as well.

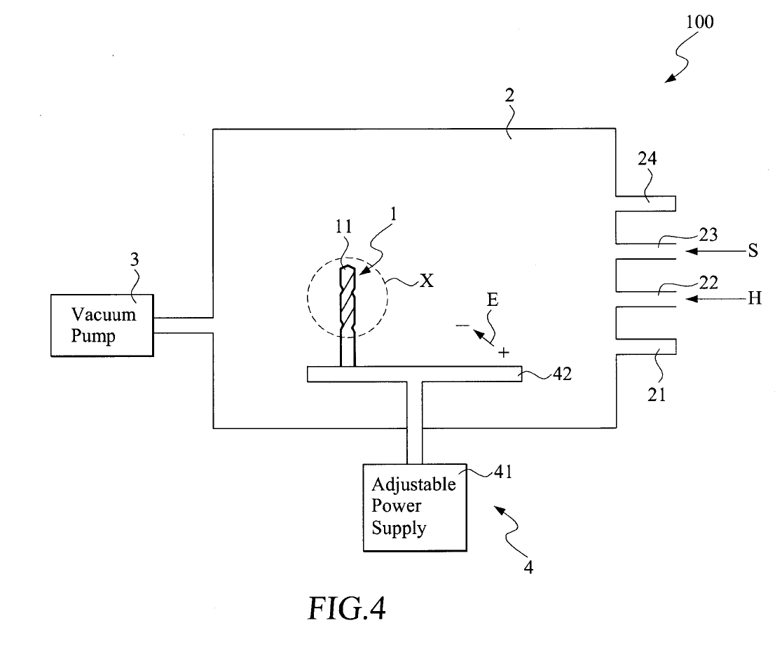

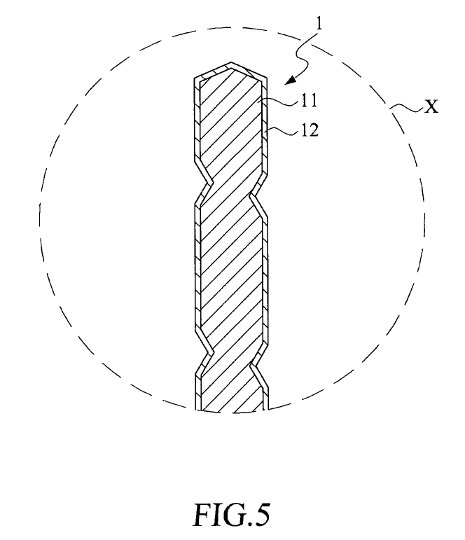

Referring to FIGS. 4 and 5, FIG. 4 illustrates how an adherent film 12 is coated onto the drill bit 11 in accordance with the present invention. FIG. 5 is an enlarged cross-sectional view of area X of FIG. 4 according to the present invention. As shown, when the adherent film 12 is coating, the inlets 21 and 24 must be closed, while the inlets 22 and 23 are opened. Thus, the hydrogen gas (H₂) and a Si-containing gas can be respectively introduced into the coating chamber 2, preferably at a constant flow rate, and decomposed intom plasma by the bias electrical field E. Thereby, the adherent film 11 can be coated onto the drill bit 11 so as to provide a comprehensive adhesion between the adherent film 12 and the drill 11.

During the formation of the adherent film 12, the operation duration can be 1˜5 minutes, and the flow rate of the hydrogen gas (H₂) can be maintained between 45˜60 sccm. In the present invention, the Si-containing gas can be a Silane gas (SiH₄), a silicon tetrafluoride gas (SiF₄), a tetrachlorosilane gas (SiCl₄), or a tetramethylsilane gas (Si(CH₃)₄). If the Si-containing gas is the tetramethylsilane gas (Si(CH₃)₄), the flow rate is preferably maintained between 180˜250 sccm. The power for the adjustable power supply 41 is maintained at 1000 Watts, the bias voltage of the bias electrical field E is between 500˜600 V and the vacuum pressure inside the coating chamber 2 is adjusted between 4˜7 μbar. Upon such an arrangement, the adherent film 12 can include the Si, a silicon carbide (SiC) and a very few hydrocarbon (CₓH_{y}). The adherent film 12 having the foregoing components obviously includes a higher proportion of the Si over the conventional non-crystalline diamond like carbon (DLC) material so that the adhesion to the core drill bit 11 can be ensured.

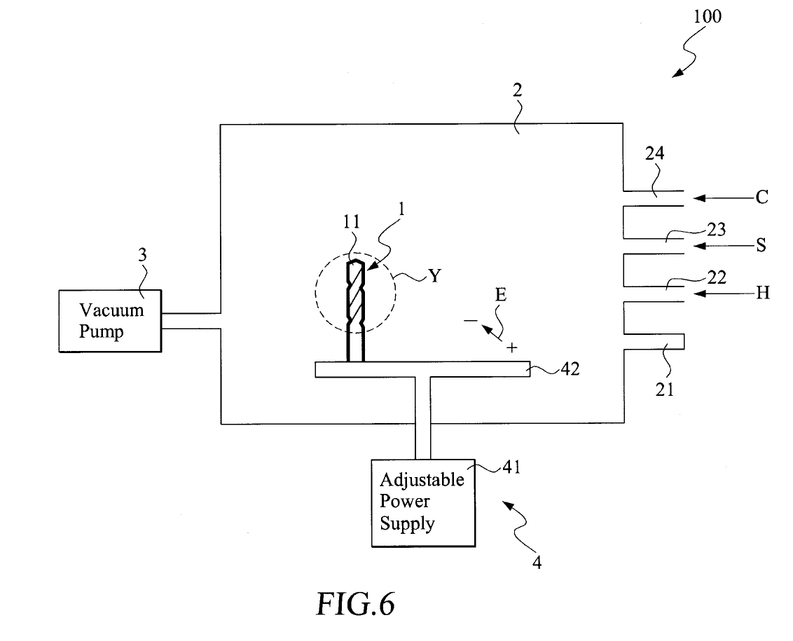

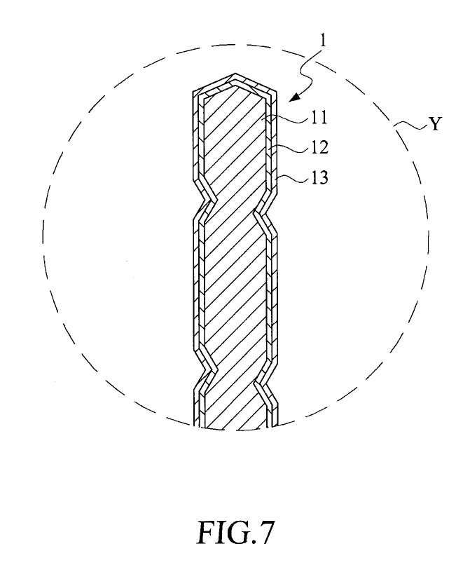

Referring to FIGS. 6-7, FIG. 6 is a schematic view showing how a mixing film 13 can be coated onto the adherent film 12 of the drill bit 11 in accordance with the present invention. FIG. 7 is an enlarged cross-sectional view of area Y of FIG. 5. In coating the mixing film 13 (as shown in FIG. 7) onto the adherent film 12, the inlet 21 must be closed, while the inlets 22, 23, 24 must be opened. The hydrogen gas (H2), the Si-containing gas and the carbon-containing gas are introduced into the coating chamber 2, and these gases can be then decomposed by the bias electrical field E so that the mixing film 13 can be coated on the adherent film 12. In the present invention, the carbon-containing gas can be a acetylene gas (C₂H₂).

During the formation of the mixing film 13, a variety of gases must be introduced into the coating chamber 2. Preferable flow rates for such gases can be respectively maintained at: 45 sccm for the hydrogen gas (H₂), 180 sccm for the Si-containing gas, and 0 sccm for any carbon-containing gas. Electricity power provided by the adjustable power supply 41 can be ranged between 1000˜1500 Watts, such that these gases in the coating chamber 2 can be kept in a plasma status. The bias voltage for the bias electrical field E can be ranged between 550˜600V. The vacuum pressure in the coating chamber 2 can be ranged between 4˜7 μbar.

After 1˜5 minutes of operation, the flow rates of the hydrogen gas (H2), the Si-containing gas and the carbon-containing gas are respectively adjusted to 800 sccm, 50 sccm and 600 sccm. The bias voltage of the bias electrical field E is shifted to the range of 400˜550V, and the vacuum pressure is adjusted to range between 13˜17 μbar. These new operation parameters can be maintained for 5 minutes so as to complete the formation of the mixing film 13, and, however, the inlet 23 must be closed in the first 2˜5 minutes so that the flow rate of the Si-containing gas can be decreased to 0 sccm.

In the present invention, the mixing film 13 includes at least the silicon carbide (SiC), the non-crystalline DLC material and a few silicon. Because the material of the mixing film 13 is similar to that of the adherent film 12 in the beginning of formation of the mixing film 13, the mixing film 13 can be firmly attached to the adherent film 12.

Meanwhile, during formation of the mixing film 13, the flow rates of the carbon-containing gas, the Si-containing gas, and the hydrogen gas are properly changed so as to have the mixing film 13 characterized in: (1) composition of the mixing film 13 being similar to that of the adherent film 12 coated directly on the core drill bit 11, and (2) composition of the DLC material of the mixing film 13 being higher than that of the adherent film 12.

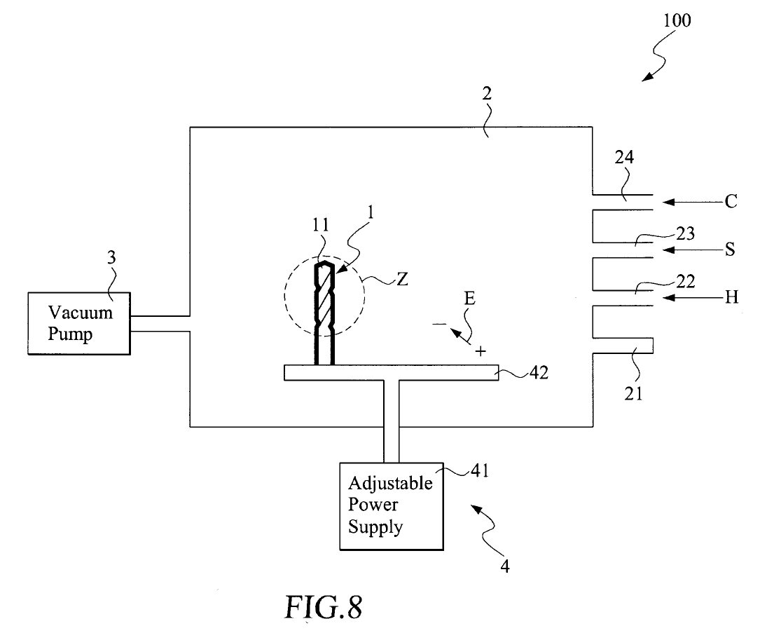

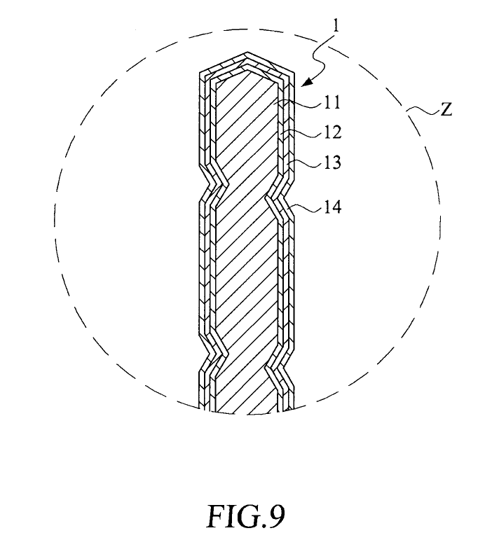

Referring to FIGS. 8 and 9, FIG. 8 is a schematic view showing how the DLC material can be further coated onto the mixing film 13 in accordance with the present invention. FIG. 9 is an enlarged cross-sectional view of the drill bit 11 in area Z of FIG. 8. When a non-crystalline DLC film 14 (as shown in FIG. 9) is to be coated on the mixing film 13, the inlets 21 and 23 must be closed, while the inlets 22 and 24 must be opened. The hydrogen gas (H₂) and the carbon-containing gas are introduced into the coating chamber 2 to be decomposed by the bias electrical field E, such that the non-crystalline DLC film 14 can be coated on the mixing film 13.

During the formation of the non-crystalline DLC film 14, the flow rate of the Si-containing gas is decreased to 0 sccm, while the flow rates of the hydrogen gas (H2) and the carbon-containing gas are respectively maintained at 800 sccm and 600 sccm. The bias voltage of the bias electrical field E, the vacuum pressure in the coating chamber 2 and the electricity power falls respectively in the ranges of around 400V, 13˜17 μbar, and around 1000 Watts. The foregoing parameters are preferably maintained at about 2 minutes so that the non-crystalline DLC film 14 can be formed.

Because the composition at the outer perimeter of the mixing film 13 is similar to the non-crystalline DLC material, the non-crystalline DLC film 14 can be firmly adhered to the mixing film 13.

As shown in FIG. 9, the film-coated drill bit 1 has the core drill bit 11, the adherent film 12 coated directly on the core drill bit 11, the mixing film 13 coated on the adherent film 12, and the non-crystalline DLC film 14 further coated on the mixing film 13.

In the art, the coating film is not easily adhered to the drill bit. However, according to the present invention, before the non-crystalline DLC film 14 is formed, the adherent film 12 and the mixing film 13 are sequentially formed as a concrete base for firmly forming the exterior non-crystalline DLC film 14. Thus, the present invention prevents the non-crystalline DLC film 14 from peeling from the mixing film 13.

According to the present invention, the film-coated drill bit has a good adhesion in the non-crystalline DLC film 14. Thereby, the film-coated drill bit (including micro drill bits) prepared by the present invention can be thicker so that better machining performance in swarf removal, wearability, and heat-resistance, as well as the service life, of the film-coated drill bit can be substantially improved.

While the invention has been described with reference to the preferred embodiments, the description is not intended to be construed in a limiting sense. It is therefore contemplated that the appended claims will cover any such modifications or embodiments as may fall within the scope of the invention defined by the following claims and their equivalents.

What is claimed is:

1. A method for film-coating drill bits, comprising the steps of:
(a) providing a core drill bit;
(b) surface cleaning and heating the core drill bit;
(c) forming an adherent film on the core drill bit;
(d) forming a mixing film on the adherent film, the mixing film including a Diamond-Like Carbon (DLC) material and compositions for forming the adherent film; and
(e) forming a non-crystalline Diamond-Like Carbon (DLC) film on the mixing film.

2. The method as claimed in claim 1, wherein the step (b) further comprises the steps of:
(b1) providing the core drill bit within a vacuum coating chamber;
(b2) providing an electrical power inside the coating chamber so as to generate a bias electrical field;
(b3) introducing at least one gas into the coating chamber; and
(b4) converting said at least one gas into a plasma-like material to clean the core drill bit.

3. The method as claimed in claim 2, wherein a vacuum pressure within the coating chamber is initially ranged between 1.5˜4 μbar, and the vacuum pressure is increased to be ranged between 4˜7 μbar after a first 20-minute operation in the step (b).

4. The method as claimed in claim 2, wherein a duration of the step (c) is 1˜5 minutes and the vacuum pressure is maintained between 4˜7 μbar; wherein, during the step (d), the vacuum pressure is initially adjusted to be ranged between 4˜7 μbar and, after first 1˜5 minutes, the vacuum pressure is increased from a range of 4˜7 μbar to a range of 13˜17 μbar for 5 more minutes; wherein, during the step (e), the vacuum pressure is ranged between 13˜17 μbar for 2 minutes so as to form the DLC material.

5. The method as claimed in claim 2, wherein, during the step (b), an adjustable power supply is included to provide the electrical power to produce the bias electrical field, wherein the electrical power is initially 300 watts and a bias voltage of the bias electrical field is 300V; wherein, after first 20 minutes, the electrical power is increased to 600 watts and the bias voltage is increased between 500˜600V; and, wherein the electrical power is further increased to 1000 watts so as to adjust the bias voltage to 550V for maintaining 20 more minutes to clean and further heat the core drill bit.

6. The method as claimed in claim 2, wherein, during the step (c), the bias voltage of the bias electrical field is ranged between 550˜600V; wherein, during the step (d), the bias voltage is decreased from a range between 550˜600V to another range between 400˜550V; and wherein, during the step (e), the bias voltage is adjusted to 1000V.

7. The method as claimed in claim 2, wherein, during the step (b), said at least one gas includes a hydrogen gas (H₂) and an argon gas (Ar).

8. The method as claimed in claim 7, wherein, during the step (b), the hydrogen gas (H₂) and argon gas (Ar) with respective flow rates of 20 sccm and 50 sccm are initially supplied to the coating chamber, and, after 20 minutes, flow rates of the hydrogen gas (H₂) and argon gas (Ar) are respectively increased to be ranged between 45˜60 sccm and between 200˜250 sccm.

9. The method as claimed in claim 2, wherein, during the step (c), a hydrogen gas (H₂) and a Si-containing gas are decomposed to coat on the core drill bit such that the adherent film includes a silicon, a silicon carbide (SiC) and a hydrocarbon (CₓH_{y}), in which the hydrogen (H₂) providing to the coating chamber has a flow rate between 45˜60 sccm and the Si-containing gas has a flow rate between 180˜250 sccm.

10. The method as claimed in claim 2, wherein, during the step (d), a hydrogen gas (H₂) and a Si-containing gas, and a Carbon-containing gas are decomposed to coat on the core drill bit so as to form the adherent film.

11. The method as claimed in claim 10, wherein, during the step (d), the hydrogen (H₂), the Si-containing gas, and the Carbon-containing gas are respectively introduced into the coating chamber with respective flow rates at 45 sccm, 180 sccm and 0 sccm; after 1˜5 minutes, the hydrogen (H₂), the Si-containing gas, and the Carbon-containing gas are respectively introduced into the coating chamber with respective flow rates at 800 sccm, 50 sccm and 600 sccm; and, 2˜5 more minutes later, the Si-containing gas, and the Carbon-containing gas are respectively introduced into the coating chamber with respective flow rates at 800 sccm, 50 sccm and 0 sccm; such that the mixing film is formed to has the same compositions as those of the non-crystalline Diamond-Like Carbon (DLC) film and the adherent film.

12. The method as claimed in claim 10, wherein the Carbon-containing gas is an acetylene gas (C₂H₂), and the Si-containing gas is a tetramethylsilane (Si(CH₃)₄) gas.

13. A film-coated drill bit, comprising:
a core drill bit;
an adherent film, coated directly on the core drill bit;
a mixing film, coated on the adherent film and including compositions of the adherent film and a non-crystalline Diamond-Like Carbon (DLC) material, and
a non-crystalline Diamond-Like Carbon (DLC) film, coated on the mixing film;
wherein the composition of DLC material in the mixing film is higher at a position thereof close to the DLC film.

14. The method as claimed in claim 13, wherein the adherent film includes a silicon, a silicon carbide (SiC) and a hydrocarbon (CₓH_{y}), and the mixing film includes also the silicon carbide (SiC) and the silicon to ensure that the mixing film is firmly adhered to the adherent film.
